(19) United States
(12) Patent Application Publication
(10) Pub. No.: US 2007/0210303 A1
(43) Pub. Date: Sep. 13, 2007

(54) Thin film transistor and organic electroluminescent display device

(76) Inventors: Kyoji Ikeda, Gifu (JP); Shingo Nakai, Aichi (JP); Takashi Ogawa, Gifu (JP); Kenya Uesugi, Gifu (JP)

Correspondence Address: MORRISON & FOERSTER LLP, 1650 TYSONS BOULEVARD, SUITE 400, MCLEAN, VA, 22102, US

(21) Appl. No.: 11/546,550

(22) Filed: Oct. 12, 2006

(30) Foreign Application Priority Data
Oct. 13, 2005 (JP) 2005-298943

(51) Int. Cl. H01L 29/08

(52) U.S. Cl. 257/40

(57) ABSTRACT

A photoelectric current caused by extraneous light is suppressed and variations in characteristics (for example, a threshold voltage) of a thin film transistor are reduced. An active layer (semiconductor layer) made of polycrystalline silicon, which is transformed from amorphous silicon by laser annealing, is formed on an insulating substrate. A drain region 2d and a source region 2s, which are facing to each other, are formed in the active layer. Each of the drain region 2d and the source region 2s is formed of an n⁻ layer and an n⁺ layer adjacent to each other. A p-type channel region 2c is formed between the n⁻ layer in the drain region 2d and the n⁻ layer in the source region 2s. A light-shielding layer 3d is formed to cover only a boundary region between the n⁻ layer in the drain region 2d and the channel region 2c to shield the boundary region from extraneous light incident upon the boundary region through the insulating substrate.

### CROSS-REFERENCE OF THE INVENTION

This application claims priority from Japanese Patent Application No. 2005-298943, the content of which is incorporated herein by reference in its entirety.

### BACKGROUND OF THE INVENTION

1. Field of the Invention

This invention relates to a thin film transistor and an organic electroluminescent display device.

2. Description of the Related Art

Organic EL display devices using organic electroluminescent elements (hereafter referred to as organic EL elements), that are self-light-emitting elements, have been developed in recent years as display devices to replace a CRT and an LCD. An emphasis is laid on development of an active matrix type organic EL display device, each pixel of which is provided with a drive transistor to drive an organic EL element in response to a video signal.

The drive transistor is composed of a thin film transistor formed on a glass substrate. Extraneous light enters through the glass substrate an active layer in the thin film transistor in a bottom emission type organic EL display device that emits light from the organic EL element through the glass substrate. There arises a problem that contrast of the display is deteriorated, since the extraneous light excites carriers in the active layer in the thin film transistor to cause a photoelectric current (leakage current) between a source and a drain of the thin film transistor.

A technology to suppress the photoelectric current by providing a light-shielding layer that shields the active layer in the thin film transistor from incident light is known as disclosed in Japanese Patent Application Publication No. 2004-134356.

In a conventional thin film transistor, however, an electric potential at the light-shielding layer exerts a considerable influence upon characteristics (for example, a threshold voltage) of the thin film transistor. Fixing the electric potential at the light-shielding layer is conceivable. With the fixed electric potential at the light-shielding layer, however, the characteristics of the thin film transistor are influenced by a forward current across a p-n junction associated with the transistor and a kickback current (a leakage current from the drain to the source). If the electric potential at the light-shielding layer is not fixed, on the other hand, the electric potential at the light-shielding layer becomes unstable because of electrostatic charging, thereby causing a problem that the characteristics of the transistor become even more unstable. When such a thin film transistor is used as the drive transistor in the organic EL display device, there arises a problem that quality of the display is exacerbated.

### SUMMARY OF THE INVENTION

This invention provides a thin film transistor having a semiconductor layer formed on a insulating substrate, a source and a drain of a first conductivity type formed in the semiconductor layer, a channel region formed in the semiconductor layer between the source region and the drain region, a light-shielding layer covering only a boundary region between the drain region and the channel region to shield the boundary region from extraneous light incident upon the boundary region through the insulating substrate, a gate insulation film formed on the semiconductor layer, and a gate electrode formed on the gate insulation film.

The light-shielding layer is formed to cover only the boundary region, considering that a primary region where a photoelectric current is generated by an influence of the extraneous light is the reverse biased boundary region between the drain region and the channel region. As a result, the generation of the photoelectric current can be suppressed and variations in characteristics (for example, a threshold voltage) of the thin film transistor can be reduced.

This invention also provides an organic electroluminescent display device having an electroluminescent element formed on an insulating substrate and emits light through the insulating substrate and a thin film transistor that drives the organic electroluminescent element, wherein the thin film transistor includes a semiconductor layer formed on the insulating substrate, a source and a drain of a first conductivity type formed in the semiconductor layer, a channel region formed in the semiconductor layer between the source region and the drain region, a light-shielding layer covering only a boundary region between the drain region and the channel region to shield the boundary region from extraneous light incident upon the boundary region through the insulating substrate, a gate insulation film formed on the semiconductor layer, and a gate electrode formed on the gate insulation film.

### BRIEF DESCRIPTION OF THE DRAWINGS

FIG. 1 is a cross-sectional view of an n-channel type thin film transistor according to a first embodiment of this invention.

FIG. 2 is a cross-sectional view of an n-channel type thin film transistor compared with the n-channel type thin film transistor of this invention.

FIG. 3 is a cross-sectional view of an n-channel type thin film transistor according to a second embodiment of this invention.

FIG. 4A shows drain current versus gate voltage characteristic curves of the n-channel type thin film transistor according to the first embodiment of this invention. FIG. 4B shows drain current versus gate voltage characteristic curves of the n-channel type thin film transistor compared with the thin film transistor of this invention.

FIG. 5A shows drain current versus gate voltage characteristic curves of a p-channel type thin film transistor according to the first embodiment of this invention. FIG. 5B shows drain current versus gate voltage characteristic curves of a p-channel type thin film transistor compared with the thin film transistor of this invention.

FIG. 6 is a cross-sectional view of a pixel in an organic EL display device according to a third embodiment of this invention.

FIG. 7 is a circuit diagram of the pixel in the organic EL display device according to the third embodiment of this invention.

FIG. 8 is a circuit diagram of a pixel in an organic EL display device according to a fourth embodiment of this invention.

FIG. 9 is a circuit diagram of a pixel in an organic EL display device according to a fifth embodiment of this invention.

### DETAILED DESCRIPTION OF THE INVENTION

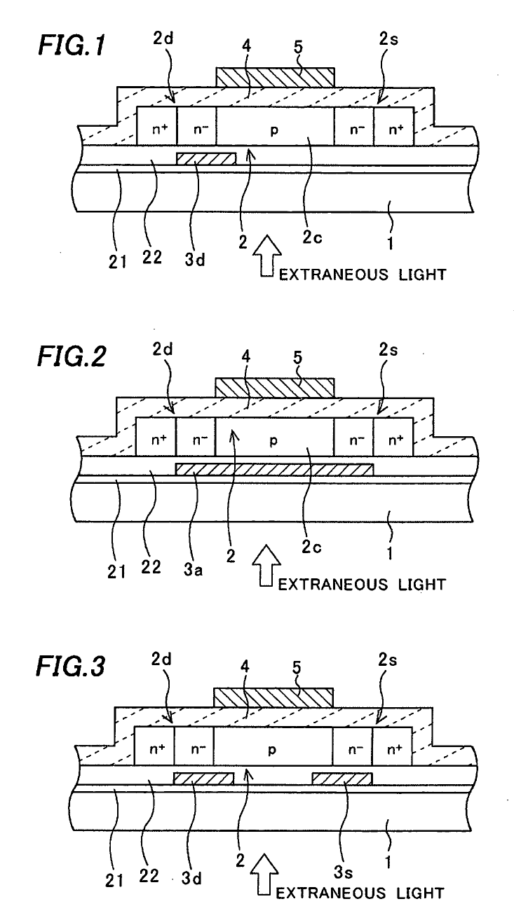

Next, a thin film transistor according to a first embodiment of this invention will be explained referring to the drawings. FIG. 1 is a cross-sectional view of a thin film transistor according to the first embodiment. An active layer (semiconductor layer) 2 made of polycrystalline silicon, that is transformed from amorphous silicon by laser annealing, is formed on an insulating substrate 1 made of quartz glass, non-alkali glass or the like. A drain region 2d and a source region 2s are formed in the active layer facing to each other. The drain region 2d and the source region 2s are formed to make a so-called LDD (Lightly Doped Drain) structure, which means that each of them is formed of an n⁻ layer and an n⁺ layer adjacent to each other. A p-type channel region 2c is formed in the active layer 2 between the n⁻ layer in the drain region 2d and the n⁻ layer in the source region 2s.

A light-shielding layer 3d is formed to cover only a boundary region between the n⁻ layer in the drain region 2d and the channel region 2c to shield the boundary region from extraneous light incident upon the boundary region through the insulating substrate 1. The light-shielding layer 3d is interposed between the insulating substrate 1 and the active layer 2, and is made of metal such as chromium or molybdenum. The light-shielding layer 3d is formed on a buffer insulating layer 21 on the insulating substrate 1. An insulating film 22 is interposed between the light-shielding layer 3d and the active layer 2. A gate insulating film 4 made of insulating material such as SiO₂ is formed to cover the active layer 2. A gate electrode 5 made of chromium, molybdenum or the like is formed on the gate insulating film 4.

FIG. 2 is a cross-sectional view of a thin film transistor, for comparison with the thin film transistor of this embodiment. A light-shielding layer 3d of the thin film transistor shown in FIG. 2 is formed to provide an active layer 2 with light-shielding over most of its longitudinal direction, while the light-shielding layer 3d of the thin film transistor of this embodiment shown in FIG. 1 is formed to cover only the boundary region between the drain region 2d and the channel region 2c. The thin film transistor of the first embodiment is referred to as a “drain-light-shielded” thin film transistor and the thin film transistor that is compared with the thin film transistor of the first embodiment and shown in FIG. 2 is referred to as a “full-light-shielded” thin film transistor hereafter.

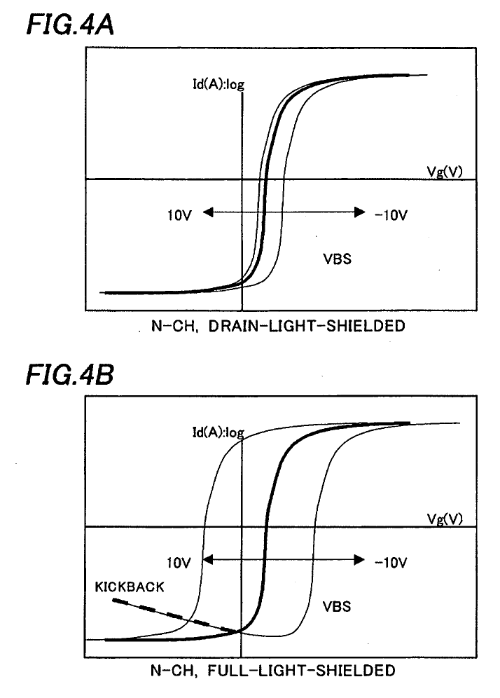

FIG. 4A shows drain current versus gate voltage characteristic curves of the drain-light-shielded thin film transistor, and FIG. 4B shows drain current versus gate voltage characteristic curves of the full-light-shielded thin film transistor. In FIGS. 4A and 4B, Id(A) denotes the drain current, Vg(V) denotes the gate voltage and VBS denotes a voltage applied between the light-shielding layer_3d or 3a and the source region 2s. VBS varies in a range between −10V and 10V. A p-n junction between the p-type channel region 2c and the n layer in the drain region 2d or in the source region 2s is reverse biased when VBS is negative, and the p-n junction is forward biased when VBS is positive.

As shown in FIG. 4B, the drain current versus gate voltage characteristic curve of the full-light-shielded thin film transistor shifts to the right significantly when VBS varies to a negative direction, and shifts to the left significantly when VBS varies to a positive direction. In a region where VBS is positive, a forward current flows because the p-n junction is forward biased. That is, a threshold voltage of the thin film transistor is significantly varied in both directions by the variation in VBS. In addition, a kickback current flows in a region where VBS <−8V when the thin film transistor is turned off (Vg(V)<0V).

On the other hand, a shift in the drain current versus gate voltage characteristic curve of the drain-light-shielded thin film transistor due to the variation in VBS is very small, as shown in FIG. 4A. Also, the kickback current does not flow, although the threshold voltage increases slightly when VBS varies to the negative direction. The threshold voltage scarcely varies and no forward current flows when VBS varies in the negative direction.

As described above, while the characteristics of the full-light-shielded thin film transistor vary significantly when the electric potential at the light-shielding layer 3a varies, the variation in the characteristics of the drain-light-shielded thin film transistor of this invention is suppressed when the electric potential at the light-shielding layer 3d varies.

Since a primary region where the photoelectric current is generated by the influence of the extraneous light is the boundary region between the drain region 2d and the channel region 2c due to the operating condition of the thin film transistor, the light-shielding layer 3d covering only the boundary region can sufficiently suppress the generation of the photoelectric current. It is preferable for suppressing the variation in VBS and suppressing the variation in the characteristics of the thin film transistor that the electric potential at the light-shielding layer 3d is fixed at a certain electric potential, for example, at the ground voltage Vss.

It this embodiment, the p-n junction associated with the drain region 2d is reverse biased and the p-n junction associated with the source region 2s is not reverse biased. In other biasing conditions, that is, when the p-n junction associated with the source region 2s is reverse biased, the drain-light-shielding is not effective to suppress the photoelectric current because the photoelectric current is generated there.

Considering the above, a thin film transistor according to a second embodiment of this invention is provided with a second light-shielding layer 3s that covers only a boundary region between the source region 2s and the channel region 2c, in addition to the drain-light-shielding layer (a first light-shielding layer) 3d, as shown in FIG. 3. The insulating film 22 is also interposed between the second light-shielding layer 3s and the active layer 2.

This thin film transistor is effective to suppress the generation of the photoelectric current when the p-n junction associated with the drain region 2d is reverse biased and when the p-n junction associated with the source region 2s is also reverse biased. In addition, because it is not full-light-shielded, the variation in the characteristics due to the variation in the electric potential at the light-shielding layer 3d and the light-shielding layer 3s is suppressed to some extent.

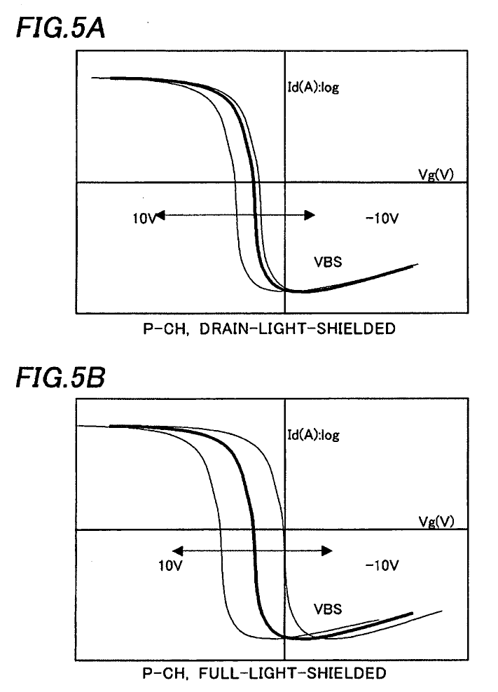

Although the first and second embodiments are described for the n-channel type thin film transistors, variation in characteristics of a p-channel type thin film transistor can also be suppressed by forming a similar light-shielding layer. That is, shifts due to the variation in VBS in drain current versus gate voltage characteristic curves of a drain-light-shielded p-channel type thin film transistor shown in FIG. 5A is suppressed and is made less than those of the full-light-shielded p-channel type thin film transistor shown in FIG. 5B.

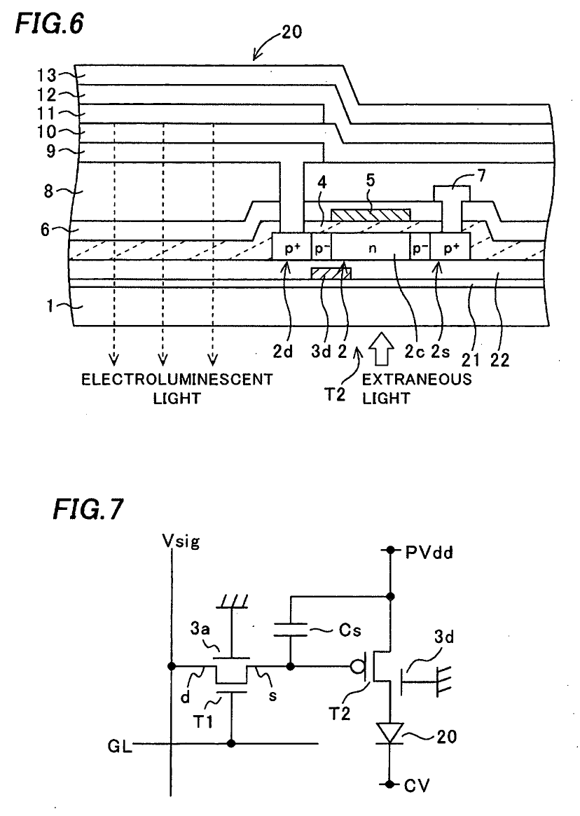

Next, an organic EL display device using the thin film transistor of this invention will be explained. FIG. 6 is a cross-sectional view of one of pixels in a bottom emission type organic EL display device according to a third embodiment of this invention. The drain-light-shielded thin film transistor of the first embodiment is used as a drive transistor T2 to drive an organic EL element 20. The drive transistor T2 is made of a p-channel type thin film transistor in this embodiment. A structure of the pixel in the organic EL display device is described in detail hereafter.

The drain-light-shielded drive transistor T2 is formed on the insulating substrate 1. An interlayer insulating film 6 made of films of SiO₂, SiN and SiO₂, stacked in the order described above, is formed to cover the drive transistor T2. A drive power supply line 7 connected with a drive power supply electric potential PVdd is formed in a contact hole corresponding to the source region 2s by filling the contact hole with metal such as aluminum. A planarizing insulating film 8 made of organic resin, for example, is formed over the entire surface to planarize it.

A contact hole is formed in the planarizing insulating film 8 at a location corresponding to the drain region 2d. A transparent electrode made of ITO (Indium Tin Oxide) or IZO (Indium Zinc Oxide) is formed on the planarizing insulating film 8, making contact with the source region 2s through the contact hole. The transparent electrode makes an anode layer 9 of the organic EL element 20. The anode layer 9 is formed to make an isolated island in each of the pixels.

The organic EL element 20 has a structure in which the anode layer 9, a first hole transporting layer made of MTDATA (4, 4-bis (3-methylphenylphenylamino) biphenyl), a second hole transporting layer made of TPD (4, 4, 4-tris (3-methylphenylphenylamino) triphenylanine), a luminescent layer 11 made of Bebq2 (10-benzo[h]quinolinol-berylium complex) containing a quinqcridone derivative, an electron transporting layer 12 made of Bebq2, and a cathode layer 13 made of magnesium/indium alloy, aluminum or aluminum alloy are stacked in the order described above.

The cathode layer 13 covers the luminescent layer 11 and extends all over the pixel region. In the organic EL element 20, holes injected from the anode layer 9 and electrons injected from the cathode layer 13 are recombined with each other in the luminescent layer 11 to excite organic molecules constituting the luminescent layer 11, thereby generating excitons. Light is generated in the luminescent layer II in a radiative decaying process of the excitons. The light is emitted from the transparent anode layer 9 through the transparent or semitransparent insulating substrate 1 to the outside, thereby causing the element to perform light emission.

Because the organic EL display device described above is provided with the light-shielding layer 3d over the drain region of the thin film transistor, display contrast can be improved by suppressing the photoelectric current (off leakage current) as well as reducing variation in the characteristics (variation in the threshold voltage, for example) of the thin film transistor.

FIG. 7 is a circuit diagram of one of the pixels in the organic EL display device according to the third embodiment of this invention. A pixel selection transistor T1 is shown in the circuit diagram, in addition to the drive transistor T2. The pixel selection transistor T1 is turned on in response to a gate signal on a gate line GL to transfer a video signal Vsig to the gate of the drive transistor T1. A storage capacitor Cs retains the video signal Vsig. The pixel selection transistor T1 is of n-channel type and the drive transistor T2 is of p-channel type.

When illuminated by extraneous light as intensive as 100,000 lux, a photoelectric current (off leakage current) is caused in the pixel selection transistor T1 to discharge the charges stored at the gate of the drive transistor T2. As a result, there is caused vertical interference among the pixels, that is, display failure due to crosstalk. In order to avoid it, the pixel selection transistor T1 also needs to be provided with a light-shielding layer. As for the pixel selection transistor T1, there is a case in which a p-n junction associated with a drain d is reverse biased, while there is another case in which a p-n junction associated with a source s is reverse biased. Therefore, shielding the drain d only or shielding the source s only is not enough to obtain the effect of the shielding. Considering the above, the pixel selection transistor T1 in the circuit shown in FIG. 7 is provided with a full-light-shielding layer 3a. Although the variation in the threshold voltage is large with the full-light-shielding as described above, influence of the variation is not significant when the high level voltage of the gate signal is significantly higher than the threshold voltage.

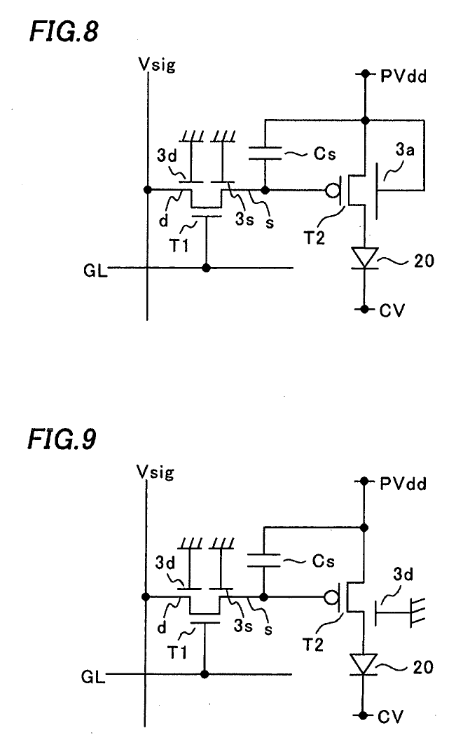

Or, the pixel selection transistor T1 may be provided with a source-light-shielding layer 3s (Refer to FIG. 3.) and a drain-light-shielding layer 3d according to the second embodiment, as shown in a circuit diagram of one of pixels in a organic EL display device according to a fourth embodiment of this invention, which is shown in FIG. 8. In the circuit shown in FIG. 8, a drive transistor T2 is provided with a full-light-shielding layer 3a. Although the variation in the threshold voltage of the drive transistor T2 is large in this case also, the influence of the variation is not significant when the high level voltage of the video signal Vsig is significantly higher than the threshold voltage.

FIG. 9 shows a circuit diagram of one of pixels in an organic EL display device according to a fifth embodiment of this invention. It is the most preferable circuit in which a drive transistor T2 is provided with a drain-light-shielding layer 3d while a pixel selection transistor T1 is provided with a drain-light-shielding layer 3d and a source-light-shielding layer 3s (Refer to FIG. 3.). As a result, the photoelectric current (off leakage current) caused by the extraneous light can be suppressed to improve the display contrast and the variation in the characteristics (the variation in the threshold voltage, for example) of the transistor can be reduced regardless the high level voltage of the gate signal and the video signal Vsig, for both the drive transistor T2 and the pixel selection transistor T1.

With the thin film transistors of these embodiments, the variation in the characteristics (threshold voltage, for example) of the thin film transistor can be reduced, while the photoelectric current caused by the extraneous light can be suppressed. In particular, the kickback current as well as the forward current can be suppressed.

When the light-shielding layer covers the channel region, it serves as a back gate and varies the characteristics of the thin film transistor. Therefore, it is required that the light-shielding layer does not cover the channel region entirely in order to suppress the back gate bias effect. It is preferable that the light-shielding layer does not cover at least a half of the channel region, i.e., covering only the half of the channel region or less. It is more preferable that the light-shielding layer does not cover ¾ of the channel region, i.e., covering only ¼ or less.

Also, with the organic electroluminescent display device of these embodiments, the display contrast can be improved because the organic electroluminescent element is driven by the thin film transistor described above.

What is claimed is:

1. A thin film transistor comprising:
an insulating substrate;
a semiconductor layer disposed on the insulating substrate and comprising a source region, a drain region and a channel region disposed between the source region and the drain region;
a light-shielding layer covering a boundary between the drain region and channel region and extending from the boundary so as not to cover a part of the channel region, the light-shielding layer being configured to shield light incident on the boundary through the insulating substrate;
a gate insulating film covering the semiconductor layer; and
a gate electrode disposed on the gate insulating film.

2. The thin film transistor of claim 1, further comprising an insulating film disposed between the light-shielding layer and the semiconductor layer, wherein the light-shielding layer is disposed between the insulating substrate and the semiconductor layer.

3. The thin film transistor of claim 1, wherein the light-shielding layer is configured to be at a predetermined potential.

4. The thin film transistor of claim 2, wherein the light-shielding layer is configured to be at a predetermined potential.

5. The thin film transistor of claim 1, wherein the drain region comprises a low impurity concentration region and a high impurity concentration region, and the light-shielding layer does not cover the high impurity concentration region.

6. The thin film transistor of claim 1, wherein the light-shielding layer comprises chromium or molybdenum.

7. A thin film transistor comprising:
an insulating substrate;
a semiconductor layer disposed on the insulating substrate and comprising a source region, a drain region and a channel region disposed between the source region and the drain region;
a first light-shielding layer covering a first boundary between the drain region and channel region and extending from the first boundary so as not to cover a part of the channel region, the light-shielding layer being configured to shield light incident on the first boundary through the insulating substrate;
a second light-shielding layer covering a second boundary between the source region and channel region and extending from the second boundary so as not to cover a part of the channel region, the light-shielding layer being configured to shield light incident on the second boundary through the insulating substrate;
a gate insulating film covering the semiconductor layer; and
a gate electrode disposed on the gate insulating film.

8. The thin film transistor of claim 7, further comprising an insulating film disposed between the first and second light-shielding layers and the semiconductor layer, wherein the first and second light-shielding layers are disposed between the insulating substrate and the semiconductor layer.

9. The thin film transistor of claim 7, wherein the first and second light-shielding layers are configured to be at a predetermined potential.

10. The thin film transistor of claim 8, wherein the first and second light-shielding layers are configured to be at a predetermined potential.

11. The thin film transistor of claim 7, wherein the first and second light-shielding layers comprise chromium or molybdenum.

12. An organic electroluminescent device comprising:
an insulating substrate;
an organic electroluminescent element formed on the insulating substrate and emitting light through the insulating substrate; and
a drive transistor formed on the insulating substrate and configured to drive the organic electroluminescent element, the drive transistor comprising a semiconductor layer comprising a source region, a drain region and a channel region disposed between the source region and the drain region, and further comprising a light-shielding layer covering a boundary between the drain region and channel region and extending from the boundary so as not to cover a part of the channel region, a gate insulating film covering the semiconductor layer, and a gate electrode disposed on the gate insulating film,
wherein the light-shielding layer is configured to shield light incident on the boundary through the insulating substrate.

13. The organic electroluminescent device of claim 12, further comprising an insulating film disposed between the light-shielding layer and the semiconductor layer, wherein the light-shielding layer is disposed between the insulating substrate and the semiconductor layer.
